(19) United States
(12) Patent Application Publication
(10) Pub. No.: US 2024/0358127 A1
(43) Pub. Date: Oct. 31, 2024

(54) EXTERNAL PART FOR WATCHES OR JEWELLERY COMPRISING A COATING OF SATURATED INTRINSIC COLOUR AND METHOD FOR MANUFACTURING SAID EXTERNAL PART

(71) Applicant: The Swatch Group Research and Development Ltd, Marin (CH)

(72) Inventors: Marta FORNABAIO, Crissier (CH); Lucie TABARD, Neuchatel (CH); Vladislav SPASSOV, Praz (CH); Loïc CURCHOD, Lausanne (CH)

(73) Assignee: The Swatch Group Research and Development Ltd, Marin (CH)

(21) Appl. No.: 18/611,984

(22) Filed: Mar. 21, 2024

(30) Foreign Application Priority Data
Apr. 27, 2023 (EP) 23170406.5

(51) Int. Cl. A44C 27/00; C23C 14/58; G04B 45/00; G04D 3/00

(52) U.S. Cl. CPC A44C 27/007; G04B 45/0076; G04D 3/0092; C23C 14/586

(57) ABSTRACT

A watch or jewellery external part, in which the external part includes a substrate on a surface of which extends a coating including a tantalum Ta based nitride or oxynitride having a thickness comprised between 300 nm and 10 μm and an intrinsic and saturated colour.

### TECHNICAL FIELD OF THE INVENTION

The invention relates to the field of watchmaking or jewellery, and more particularly relates to a watch or jewellery external part comprising an intrinsically coloured coating, and a method for manufacturing said external part.

In this text, the term “external part” refers to any decorative article in the fields of watchmaking or jewellery, for example consisting of a case, dial, dial applique, hand, bezel, crown, bracelet links, etc. intended to be visible to a user.

Preferably, the present invention relates to a watch or jewellery external part comprising a coating whose intrinsic colour is a shade of red.

### TECHNOLOGICAL BACKGROUND

In the watchmaking or jewellery field, and more generally in the decorative article field, deposition methods by painting, varnishing or enamelling are not always appropriate.

Indeed, on the one hand, the layer of material applied to the surface of an article to be decorated is too thick to reveal any surface structuring, for example a brushed, sunray-brushed, sandblasted or laser-structured surface, etc., and on the other hand, the lifespan of this layer and consequently its colour is not always satisfactory.

Thus, thin layer vacuum deposition techniques such as physical vapour deposition (PVD), chemical vapour deposition (CVD) and atomic layer deposition (ALD) are preferred. Indeed, these thin layer vacuum deposition techniques enable the deposition of thin, resistant layers, which are typically suitable for coating small, friction-prone parts and comprising for example fine surface structuring.

However, despite the fact that these deposition techniques allow to obtain coatings of a multitude of intrinsic colours, the implementation of these methods does not allow to obtain certain specific intrinsic colours, such as shades of red, in particular a bright and vivid red, on an industrial scale.

It is also known to deposit a stack of thin layers to create an interferential optical system for generating a given colour. However, the perception of the colour is likely to depend on the viewing angle. Moreover, the stacking of thin layers has significant manufacturing constraints in so far as the colour generated is highly dependent on the thickness of the thin layers.

There is therefore a need to obtain an external part with a bright and saturated colour, for example red, obtained by one or more thin layers to preserve the structure of the substrate, the appearance of which does not vary with a user's viewing angle, and which is adapted to be subjected to mechanical stress without degrading.

### SUMMARY OF THE INVENTION

To this end, the present invention relates to a watch or jewellery external part comprising a substrate on a surface of which extends a coating comprising a tantalum Ta based metal nitride or oxynitride whose thickness is comprised between 300 nm and 10 μm so as to have a predetermined colour.

In particular embodiments, the invention may further include one or more of the following features, taken alone or in any technically possible combination.

In particular embodiments, the coating has a thickness comprised between 1 μm and 3 μm, preferably 2 μm.

In particular embodiments, a red coating is made of tantalum nitride Ta with a stoichiometry substantially close to or equal to Ta₃N₅, so as to have a bright red colour.

In particular embodiments, the coating is produced with an addition of oxygen in the range 0-5 atomic %.

In particular embodiments, the coating has a red colour characterised by coordinates a* and b* greater than 20, preferably greater than 50, even more preferably by coordinates L*=[30; 50], a*=[50; 70] and b*=[60; 80], and in particular, L*=42, a*=58 and b*=72, in CieLAB colour space in transmission mode of the standard illuminant D65, with an observer of 10° and a measurement geometry d:0°.

In particular embodiments, the coating forms a composition of the type AB(O,N), with B being tantalum Ta and A a metal element.

In particular embodiments, the metal element A is preferably selected from Ba, Ca, Nd, La, Sr, Eu and Yb. The coating then comprises a composition substantially close to or equal to respectively BaTaO₂N, CaTaO₂N, NdTaO₂N, LaTaO₂N, SrTaO₂N, EuTaO₂N or Yb₂Ta₂O₅N₂.

According to another object, the present invention relates to a method for manufacturing a watch or jewellery external part, for example as described above, comprising the steps of:
depositing a thin layer of a tantalum Ta based metal oxide on a substrate, said thin layer having a thickness comprised between 300 nm and 10 μm;
nitriding the thin layer to form a coating comprising at least one metal nitride or oxynitride.

In particular implementations, the step of nitriding the deposited layer is not complete in order to generate an oxynitride of the coating material.

In particular implementations, during the deposition step, the deposited thin layer is made of TaOₓ and the nitriding step is carried out so that the coating is made of tantalum Ta nitride with a stoichiometry substantially close to or equal to orthorhombic Ta₃N₅, so that the coating has a red colour.

In particular implementations, during the deposition step, the deposited thin layer is made of TaOₓ and is combined with at least one metal element selected from Ba, Ca, Nd, La, Sr, Eu or Yb.

In particular implementations, the nitriding step is carried out in a suitable atmosphere at a temperature comprised between 600° C. and 1200° C. for 10 h to 60 h, preferably between 700° C. and 1000° C. for 20 h to 50 h.

In particular implementations, the nitriding step is carried out in a suitable atmosphere at a temperature of 900° C. for 40 hours.

### BRIEF DESCRIPTION OF THE FIGURES

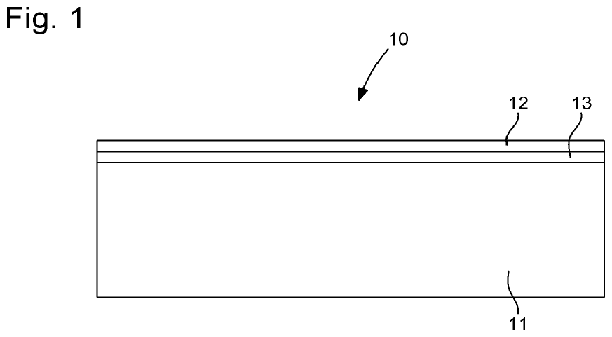

Other features and advantages of the invention will become apparent from the following detailed description, which is given as a non-limiting example, with reference to the appended FIG. 1, schematically showing a cross-sectional view of an external part according to a preferred embodiment of the invention.

Note that the figure is not necessarily drawn to scale for reasons of clarity.

### DETAILED DESCRIPTION OF THE INVENTION

The present invention relates to a watch or jewellery external part 10, as schematically shown in FIG. 1, comprising a substrate 11 on a visible surface of which extends a coating 12 comprising a metal nitride or oxynitride. The coating 12 has a predefined colour depending on the metal constituting the coating 12 as described later in the text.

The coating 12 is sufficiently thick for its colour to be saturated, while at the same time being sufficiently thin so as not to erase any structuring of the surface of the substrate 11 and so as not to affect the conformity of the external part 10. To this end, the thickness of the coating 12 is comprised between 300 nm and 10 μm, preferably between 1 μm and 3 μm. Even more preferably, the thickness of the coating 12 is 2 μm.

The material making up the substrate 11 is advantageously selected so that it can withstand the conditions of deposition of a metal oxide layer and nitriding of said layer, as described in more detail below.

For example, the substrate 11 may be made of a ceramic material, such as zirconia or sapphire, or a metal alloy, such as stainless steel, or it may be made of silicon.

Advantageously, the external part 10 may include a bonding layer 13 made of Ti, Cr or another suitable metal known to the person skilled in the art, interposed between the substrate 11 and the coating 12. The bonding layer 13 has a thickness comprised between 20 nm and 500 nm, preferably 100 nm.

In the preferred exemplary embodiment of the invention, the coating 12 is made of tantalum nitride, chemically and structurally substantially close to or equal to orthorhombic Ta₃N₅. This metal nitride has a bright red colour, that is to say saturated, defined by the coordinates below in CieLAB colour space, in reflection mode of the standard illuminant D65, with an observer at 10°, in specular reflection included (SCI, measurement geometry di:8°) and excluded (SCE, measurement geometry de:8°).

| Substrate | | | | |
|---|---|---|---|---|
| material | SCI/SCE | L* | a* | b* |
| Sapphire | SCI | 63 | 2 | 0 |
| Sapphire | SCE | 21 | 9 | 0 |
| White | SCI | 58 | 14 | −1 |
| zirconia | | | | |
| White | SCE | 24 | 38 | 17 |
| zirconia | | | | |

When the material making up the substrate 11 is sapphire, the coating 12 can be observed directly, that is to say it is arranged between an observer and the substrate 11, or indirectly, that is to say the substrate 11 is arranged between the observer and the coating 12, and therefore the latter is observed through the substrate 11. It should be noted that in the case of an application of the invention wherein the coating 12 is observed indirectly, the external part 10 does not include a bonding layer 13 so that it does not degrade the perception of the colour of the coating 12.

The table above shows the coordinates of the colour of coating 12 under direct observation, and the table below shows the coordinates of the colour of coating 12 under indirect observation.

| Substrate | | | | |
|---|---|---|---|---|
| material | SCI/SCE | L* | a* | b* |
| Sapphire | SCI | 49 | 11 | −3 |
| Sapphire | SCE | 15 | 34 | 21 |

The bright red colour of the coating 12 deposited on a sapphire substrate 11 can be characterised by the values L*=42, a*=58 and b*=72, obtained during colorimetry measurements in transmission mode of the standard illuminant D65, with an observer at 10° and a measurement geometry d:0°. Preferably, it is desired to obtain a red colour whose coordinates a* and b* are greater than 20, preferably greater than 50. More particularly, it is desired to obtain a red colour whose coordinates are L*=[30; 50], a*=[50; 70] and b*=[60; 80].

In other exemplary embodiments of the invention, the coating 12 can be formed by a composition of the type AB(O,N) with A a metal element and B tantalum Ta. This feature allows to choose metal oxynitrides of different colours, so that the coating 12 can have a wide variety of colours.

In examples, the metal element A is selected from Ba, Ca, Nd, La, Sr, Eu and Yb. The coating 12 can therefore be formed so as to have a composition substantially close to or equal to BaTaO₂N having a dark red or brown colour, CaTaO₂N having a green or yellow colour, NdTaO₂N having a red or brown colour, SrTaO₂N having an orange colour, LaTaO₂N having a red or orange colour, EuTaO₂N having a brown colour or Yb₂Ta₂O₅N₂ having a green colour.

The invention also relates to a method for manufacturing an external part 10 for a watch or jewellery, for example as described above.

The method includes a step of depositing a thin layer comprising a metal oxide on the substrate 11 so that the thin layer has a thickness selected between 300 nm and 10 μm. This deposition step is followed by a step of nitriding the thin layer to form the metal nitride or oxynitride coating 12.

Preferably, the deposited thin layer is made of TaOₓ. In particular, in this preferred example, the deposition step is carried out by implementing a PVD deposition method using a tantalum Ta target and a reactive gas consisting of O₂. In particular, the thin layer can be deposited by cathode sputtering, by vapour phase electron beam evaporation, or by arc, or by pulsed laser beam ablation.

At the end of the deposition step, the deposited thin layer is therefore made of TaOₓ and the nitriding step is carried out so that the coating 12 is made of red Ta₃N₅.

In particular, the nitriding step consists of exposing the thin layer to a suitable atmosphere, for example resulting from thermal cracking of ammonia, in the enclosure of a furnace heated to several hundred degrees Celsius for several hours. More specifically, the nitriding step is carried out at a temperature comprised between 600° C. and 1200° C. for 10 h to 60 h, and preferably between 700° C. and 1000° C. for 20 h to 50 h. In the most preferred example, the nitriding step is carried out at a temperature of 900° C. for 40 hours. By way of example, during the nitriding step, the flow rate of ammonia cracked in the enclosure of the furnace is 200 ml/min.

In one variant of the method, the nitriding of the deposited layer is not complete in order to generate an oxynitride of the coating material 12.

It is also possible, during the thin layer deposition step, to deposit a thin layer from several different metal sources or from an alloyed metal source so that, at the end of the nitriding step, the coating 12 comprises a composition of the type AB (O,N) with A a metal element and B tantalum Ta.

The manufacturing method can advantageously comprise a step of depositing a bonding layer 13 as described above, before carrying out the step of depositing the coating 12, for example by a CVD, ALD or PVD deposition method. Advantageously, the bonding layer 13 deposition step and the coating 12 deposition step can be carried out successively, in the same deposition enclosure, the pressure in said enclosure being maintained between the two depositions. These deposition steps require at least two different material sources, one of which is intended to be used to form the bonding layer 13 on the substrate 11 and one of which is intended to be used to form the coating 12 on the bonding layer 13.

More generally, it should be noted that the implementations and embodiments considered above have been described by way of non-limiting examples, and that other variants are therefore possible.

In particular, it is possible to carry out a step of selective structuring of the thin layer over its entire thickness before or after the nitriding step in order to form a specific decoration. Such a step can be carried out using photolithography methods, laser ablation, etc.

For the same purpose, it is also possible to carry out a preliminary step of structuring the surface of the substrate 11.

1. A watch or jewellery external part, wherein the external part comprises a substrate on a surface of which extends a coating comprising a tantalum Ta based nitride or oxynitride having a thickness comprised between 300 nm and 10 μm, so as to have a predetermined colour.

2. The external part according to claim 1, wherein the coating has a thickness comprised between 1 μm and 3 μm.

3. The external part according to claim 2, wherein the coating has a thickness equal to 2 μm.

4. The external part according to claim 1, wherein the coating is made of tantalum nitride, with a stoichiometry substantially close to or equal to orthorhombic Ta₃N₅.

5. The external part according to claim 1, wherein the coating is produced with an addition of oxygen in the range 0-5 atomic %.

6. The external part according to claim 1, wherein the coating has a red colour characterised by coordinates a* and b* greater than 20, in CieLAB colour space in transmission mode of the standard illuminant D65, with an observer at 10° and a measurement geometry d:0°.

7. The external part according to claim 6, wherein the coating has a red colour characterised by coordinates L*=[30; 50], a*=[50; 70] and b*=[60; 80], in CieLAB colour space in transmission mode of the standard illuminant D65, with an observer at 10° and a measurement geometry d:0°.

8. The external part according to claim 7, wherein the coating has a red colour characterised by coordinates L*=42, a*=58 and b*=72, in CieLAB colour space in transmission mode of the standard illuminant D65, with an observer at 10° and a measurement geometry d:0°.

9. The external part according to claim 1, wherein the coating forms a composition of the type AB(O,N), with B being tantalum Ta and A a metal element selected from Ba, Ca, Nd, La, Sr, Eu and Yb.

10. The external part according to claim 9, wherein the coating is made of BaTaO₂N, CaTaO₂N, NdTaO₂N, LaTaO₂N, SrTaO₂N, EuTaO₂N or Yb₂Ta₂O₅N₂.

11. A method for manufacturing a watch or jewellery external part comprising the steps of:
depositing a thin layer of a tantalum Ta based metal oxide on a substrate, said thin layer having a thickness comprised between 300 nm and 10 μm,
nitriding the thin layer to form a coating comprising at least one metal nitride or oxynitride.

12. The manufacturing method according to claim 11, wherein, during the deposition step, the deposited thin layer is made of TaOₓ and the nitriding step is carried out so that the coating is made of tantalum nitride, with a stoichiometry substantially close to or equal to orthorhombic Ta₃N₅.

13. The manufacturing method according to claim 11, wherein during the deposition step, the deposited thin layer is made of TaOₓ and is combined with at least one metal element selected from Ba, Sr, Ca, Nd, La, Eu or Yb.

14. The manufacturing method according to claim 11, wherein the nitriding step is carried out at a temperature comprised between 600° C. and 1200° C. for 10 h to 60 h.

15. The manufacturing method according to claim 14, wherein the nitriding step is carried out at a temperature of 900° C. for 40 h.
